(19) United States
(12) Patent Application Publication
(10) Pub. No.: US 2025/0194014 A1
(43) Pub. Date: Jun. 12, 2025

(54) CONNECTION SYSTEM, FLEXIBLE WIRING BOARD, AND BOARD ASSEMBLY

(71) Applicant: SUMITOMO ELECTRIC INDUSTRIES, LTD., Osaka (JP)

(72) Inventors: Takeshi INOUE, Osaka-shi (JP); Yasunori ASANO, Osaka-shi (JP)

(73) Assignee: SUMITOMO ELECTRIC INDUSTRIES, LTD., Osaka (JP)

(21) Appl. No.: 18/958,551

(22) Filed: Nov. 25, 2024

(30) Foreign Application Priority Data
Dec. 11, 2023 (JP) 2023-208292

(51) Int. Cl. H05K 1/14; H05K 1/02

(52) U.S. Cl. CPC H05K 1/141; H05K 1/0277

(57) ABSTRACT

A connection system includes a first flexible wiring board and a board assembly. The first flexible wiring board has a first base film, first wires, and first electrodes. The first base film includes a first main surface extending along a first direction. The first electrodes are each electrically connected to a corresponding one of the first wires. The board assembly has a board body and a first connector. The board body includes a third main surface. The third main surface extends along a third direction. The first connector includes first conductors. The first flexible wiring board is coupled to the first connector such that the first direction intersects the third direction obliquely. Each of the first electrodes is configured to be electrically connected to a corresponding one of the first conductors when the first flexible wiring board is coupled to the first connector.

### CROSS REFERENCE TO RELATED APPLICATIONS

This application claims the benefit of priority based on Japanese Patent Application No. 2023-208292, filed on Dec. 11, 2023, and the entire contents of the Japanese Patent Application are incorporated herein by reference.

### TECHNICAL FIELD

The present disclosure relates to a connection system, a flexible wiring board, and a board assembly.

### BACKGROUND

JP H07-114954A discloses a connection system including a printed circuit board and a flexible wiring board connected horizontally to the printed circuit board. The flexible wiring board has a plurality of leads arranged side by side in one direction. The plurality of leads are each connected to a corresponding one of a plurality of terminals of leads in the printed circuit board.

JP H10-149868A discloses a connection system including a main board and a plurality of coupling boards connected perpendicularly to the main board. Each of the coupling boards has a plurality of conductor patterns arranged side by side in one direction. The plurality of conductor patterns are each connected to a wire of the main board through a pin terminal (connection terminal portion of the main board).

### SUMMARY

A connection system according to an embodiment of the present disclosure includes a first flexible wiring board, a second flexible wiring board and a board assembly. The first flexible wiring board has a first base film, a plurality of first wires, and a plurality of first electrodes. The first base film includes a first main surface extending along a first direction. The plurality of first wires are provided in or on the first base film. The plurality of first electrodes are provided at the first main surface at a front end part of the first base film in the first direction. The plurality of first electrodes are each electrically connected to a corresponding one of the plurality of first wires. The second flexible wiring board has a second base film, a plurality of second wires, and a plurality of second electrodes. The second base film includes a second main surface extending along a second direction. The plurality of second wires are provided in or on the second base film. The plurality of second electrodes are provided at the second main surface at a front end part of the second base film in the second direction. The plurality of second electrodes are each electrically connected to a corresponding one of the plurality of second wires. A board assembly has a board body, a first connector, and a second connector. The board body includes a third main surface. The third main surface extends along a third direction. The first connector is provided at the third main surface. The first connector includes a plurality of first conductors. The second connector is provided at the third main surface. The second connector includes a plurality of second conductors. The first connector and the second connector are arranged side by side in the third direction. The first main surface faces the third main surface and each of the plurality of first electrodes is electrically connected to a corresponding one of the plurality of first conductors, when the first flexible wiring board is coupled to the first connector. The second main surface faces the third main surface and each of the plurality of second electrodes is electrically connected to a corresponding one of the plurality of second conductors, when the second flexible wiring board is coupled to the second connector. The first flexible wiring board is configured to couple to the first connector such that the first direction in which the first main surface extends intersects the third direction obliquely. The second flexible wiring board is configured to couple to the second connector such that the second direction in which the second main surface extends intersects the third direction obliquely.

### BRIEF DESCRIPTION OF THE DRAWINGS

FIG. 1 is a perspective view illustrating a connection system according to an embodiment.

FIG. 2 is a cross-sectional view of the connection system taken along line II-II illustrated in FIG. 1.

FIG. 3 is a view illustrating a main surface at a front end part of a base film of a flexible wiring board shown in FIG. 2.

FIG. 4 is an enlarged view of a connector of the connection system illustrated in FIG. 2.

FIG. 5 is a cross-sectional view illustrating a connection system according to a modification.

### DETAILED DESCRIPTION

In the connection system described in JP H07-114954A, the flexible wiring board is connected horizontally to the printed circuit board. In this case, it is difficult to arrange the plurality of leads in the flexible wiring board not only in the direction parallel to the printed circuit board but also in the direction perpendicular to the printed circuit board. Thus, it is difficult to arrange the plurality of leads in a flexible wiring board at a high density. Furthermore, in the connection system described in JP H07-114954A, each of the leads in the flexible wiring board is connected to each of terminals of the printed circuit board through a contact spring. This complicates the connection configuration between the leads and the terminals, and thus deteriorates the high frequency characteristics.

When the conductive patterns in the coupling boards and the wires of the main board are connected using connectors such as pin terminals as in the connection system described in JP H10-149868A, by perpendicularly connecting the coupling boards to the main board, the plurality of conductive patterns can be arranged side by side in two directions, and thus the plurality of conductive patterns can be arranged at a high density. However, since the structure in which the conductive patterns and the wires are electrically connected to each other by using the pin terminals is complicated, the high frequency characteristics of the connection system are still deteriorated.

According to the present disclosure, it is possible to provide a connection system, a flexible wiring board, and a board assembly in which a plurality of wires can be arranged at a high density while the deterioration of the high frequency characteristics is prevented.

### Description of Embodiments of Present Disclosure

First, the contents of embodiments of the present disclosure will be listed and explained. [1] A connection system according to an embodiment includes a first flexible wiring board, a second flexible wiring board and a board assembly. The first flexible wiring board has a first base film, a plurality of first wires, and a plurality of first electrodes. The first base film includes a first main surface extending along a first direction. The plurality of first wires are provided in or on the first base film. The plurality of first electrodes are provided at the first main surface at a front end part of the first base film in the first direction. The plurality of first electrodes are each electrically connected to a corresponding one of the plurality of first wires. The second flexible wiring board has a second base film, a plurality of second wires, and a plurality of second electrodes. The second base film includes a second main surface extending along a second direction. The plurality of second wires are provided in or on the second base film. The plurality of second electrodes are provided at the second main surface at a front end part of the second base film in the first direction. The plurality of second electrodes are each electrically connected to a corresponding one of the plurality of second wires. A board assembly has a board body, a first connector, and a second connector. The board body includes a third main surface. The third main surface extends along a third direction. The first connector is provided at the third main surface. The first connector includes a plurality of first conductors. The second connector is provided at the third main surface. The second connector includes a plurality of second conductors. The first connector and the second connector are arranged side by side in the third direction. The first main surface faces the third main surface and each of the plurality of first electrodes is electrically connected to a corresponding one of the plurality of first conductors, when the first flexible wiring board is coupled to the first connector. The second main surface faces third main surface and each of the plurality of second electrodes is electrically connected to a corresponding one of the plurality of second conductors, when the second flexible wiring board is coupled to the second connector. The first flexible wiring board is configured to couple to the first connector such that the first direction in which the first main surface extends intersects the third direction obliquely. The second flexible wiring board is configured to couple to the second connector such that the second direction in which the second main surface extends intersects the third direction obliquely.

In this connection system, the first flexible wiring board and the second flexible wiring board are arranged side by side in the third direction. The first flexible wiring board is coupled to the first connector such that the first direction in which the first main surface extends intersects the third direction obliquely. The second flexible wiring board is coupled to the second connector such that the second direction in which the second main surface extends intersects the third direction obliquely. According to this connection system, the first flexible wiring board and the second flexible wiring board extend in the first and second directions intersecting the third direction, and thus, when the first flexible wiring board and the second flexible wiring board are arranged along the third direction, interference between the first flexible wiring board and the second flexible wiring board is prevented. Thus, the first flexible wiring board and the second flexible wiring board can be arranged at a high density along the third direction. As a result, a plurality of wires can be arranged at high density not only in the fourth direction intersecting the first direction, the second direction and the third direction but also in the third direction. In addition, in the above-described connection system, each of the plurality of first electrodes is electrically connected to a corresponding one of the plurality of first conductors when the first flexible wiring board is coupled to the first connector. Each of the plurality of second electrodes is electrically connected to a corresponding one of the plurality of second conductors when the second flexible wiring board is coupled to the second connector. According to this connection system, the wires in the plurality of flexible wiring boards and the conductors in the plurality of connectors can be electrically connected with a simple structure. This can prevent the deterioration of the high frequency characteristics in the connection system. As described above, the plurality of wires can be arranged at a high density while the deterioration of the high frequency characteristics is prevented in the connection system. In addition, since the plurality of flexible wiring boards are coupled to the plurality of connectors such that the first direction and the second direction intersect the third direction obliquely, a length of the connection system along the direction orthogonal to the first direction and the second direction is reduced. This makes it possible to further reduce the height of the connection system.

[2] In the connection system according to the above [1], an inclination angle of the second flexible wiring board with respect to the third direction may be smaller than an inclination angle of the first flexible wiring board with respect to the third direction. In this case, it is possible to prevent the interference between the first flexible wiring board and the second flexible wiring board. As a result, the plurality of flexible wiring boards can be arranged at a high density, and thus the plurality of wires can be arranged at a higher density.

[3] In the connection system according to the above [1] or [2], the first connector may further include a body portion and a fixation member configured to fix the first flexible wiring board to the body portion in a state in which the first flexible wiring board is coupled to the first connector. In this case, when the first flexible wiring board is coupled to the first connector, each of the plurality of first electrodes can be electrically connected to a corresponding one of the plurality of first conductors in a stable manner.

[4] In the connection system according to the above [3], the first connector may further have a plurality of holding holes extending through the body portion and into each of which a corresponding one of the plurality of first conductors is inserted. In this case, when the first flexible wiring board is coupled to the first connector, each of the plurality of first electrodes can be electrically connected to a corresponding one of the plurality of first conductors in a more stable manner.

[5] In the connection system according any one of the above [1] to [4], the second connector may be located between the first main surface of the first base film of the first flexible wiring board and the third main surface of the board body of the board assembly. The second connector may further include a first end portion and a second end portion that are arranged side by side in the third direction. The second end portion may be located on a side of the first end portion opposite to a side where the first connector is present. At the first end portion, a distance between the first main surface and the third main surface may be larger than or equal to a length of the second connector. In this case, the plurality of wires can be arranged at a higher density.

[6] In the connection system according to any one of the above [1] to [5], each of the plurality of first electrodes may include an electrode pad that is electrically connected to a corresponding one of the plurality of first wires, and a bump provided at the electrode pad. In this case, the wires in the flexible wiring board and the conductors in the connector can be electrically connected with a simpler structure. This makes it possible to further prevent the deterioration of the high frequency characteristics in the connection system.

[7] In the connection system according to the above [6], some of the plurality of first electrodes may be a plurality of third electrodes arranged side by side in a fourth direction that intersects the first direction and the third direction. Other some of the plurality of first electrodes may be a plurality of fourth electrodes that are arranged side by side in the fourth direction and located on a side of the plurality of third electrodes opposite to a side where a front end of a front end part of the base film is present. When a fifth direction is defined as a direction orthogonal to the first main surface, a maximum value of a length along the fifth direction of the bump included in each of the plurality of fourth electrodes may be larger than a maximum value of a length along the fifth direction of the bump included in each of the plurality of third electrodes. In this case, when the first flexible wiring board is coupled to the first connector such that the first direction intersects the third direction obliquely, the plurality of first electrodes can stably support the first base film, and each of the plurality of first electrodes can more reliably come into contact with a corresponding one of the plurality of first conductors. Thus, each of the plurality of first electrodes can be electrically connected to a corresponding one of the plurality of first conductors in a stable manner.

[8] In the connection system according the above [6] or [7], the bump may have a first face that is in contact with the electrode pad, and a second face that extends along the third direction and is located on a side of the bump opposite to a side where the first face is present. The second face may be configured to come into contact with a corresponding one of the plurality of first conductors when the first flexible wiring board is coupled to the first connector. In this case, the first flexible wiring board is stably supported by the first connector through the plurality of bumps. This makes it possible to electrically connect each of the plurality of electrodes to a corresponding one of the plurality of conductors in a more stable manner.

[9] In the connection system according to the above [6] or [7], the bump may have a first face that is in contact with the electrode pad, and a second face that extends along the first direction and is located on a side of the bump opposite to a side where the first face is present. The second face may be configured to come into contact with a corresponding one of the plurality of first conductors when the first flexible wiring board is coupled to the first connector. In this case, the first flexible wiring board is stably supported by the first connector through the plurality of bumps. This makes it possible to electrically connect each of the plurality of electrodes to a corresponding one of the plurality of conductors in a more stable manner.

[10] A flexible wiring board according to an embodiment is capable of being coupled to a board assembly including a board body. The flexible wiring board includes a base film, a plurality of wires, and a plurality of electrodes. The base film has a main surface extending so as to obliquely intersect a direction in which the board body extends. The plurality of wires are provided in or on the base film. The plurality of electrodes are provided at the main surface at a front end part of the base film in the direction in which the board body extends. The plurality of electrodes are each electrically connected to a corresponding one of the plurality of wires. According to the flexible wiring board having such a configuration, the same effects as the connection system described above can be achieved.

[11] A flexible wiring board according to an embodiment includes a base film, a plurality of wires, and a plurality of electrodes. The base film has a main surface. The plurality of wires are provided in or on the base film. The plurality of electrodes are provided at the main surface at a front end part of the base film. The plurality of electrodes are each electrically connected to a corresponding one of the plurality of wires. Each of the plurality of electrodes has a surface located on a side opposite to a side where the base film is present. The surface is inclined with respect to the main surface.

According to the flexible wiring board having such a configuration, the wires in the flexible wiring board and the conductors in the counterpart connector can be electrically connected to each other with the electrodes in a simpler structure. Furthermore, it is possible to obliquely couple the flexible wiring board to the counterpart connector while electrically connecting each of the plurality of electrodes to a corresponding one of the conductors of the counterpart connector in a stable manner. From the above, it is possible to achieve a connection system in which a plurality of wires can be arranged at a high density while the deterioration of the high frequency characteristics is prevented.

[12] A board assembly according to an embodiment is a board assembly capable of being coupled to a plurality of flexible wiring boards each including a base film having a first main surface and a plurality of electrodes provided at the first main surface. The board assembly includes a board body and a plurality of connectors. The board body has a third main surface extending along a direction obliquely intersecting an extending direction of the first main surface. The plurality of connectors are arranged side by side in the extending direction of the third main surface at the third main surface and each includes a plurality of conductors. Each of the plurality of conductors is configured to be electrically connected to a corresponding one of the plurality of electrodes when the connectors are coupled to the flexible wiring boards. According to the board assembly having such a configuration, the same effects as the connection system described above can be achieved.

[13] In the board assembly according to the above [12], each of the connectors may further include a body portion and a fixation member configured to fix each flexible wiring board to the body portion in a state in which each flexible wiring board is coupled to each connector. In this case, when each flexible wiring board is coupled to each connector, each of the plurality of electrodes can be electrically connected to a corresponding one of the plurality of conductors in a stable manner.

### Details of Embodiments of Present Disclosure

Specific examples of a connection system, a flexible wiring board, and a board assembly according to embodiments of the present disclosure will be described below with reference to the drawings. In the following description, the same elements or elements having the same functions are denoted by the same reference numerals, and redundant description will be omitted. The present invention is not limited to these examples, but is defined by the scope of the claims, and is intended to include all modifications within the meaning and scope equivalent to the scope of the claims.

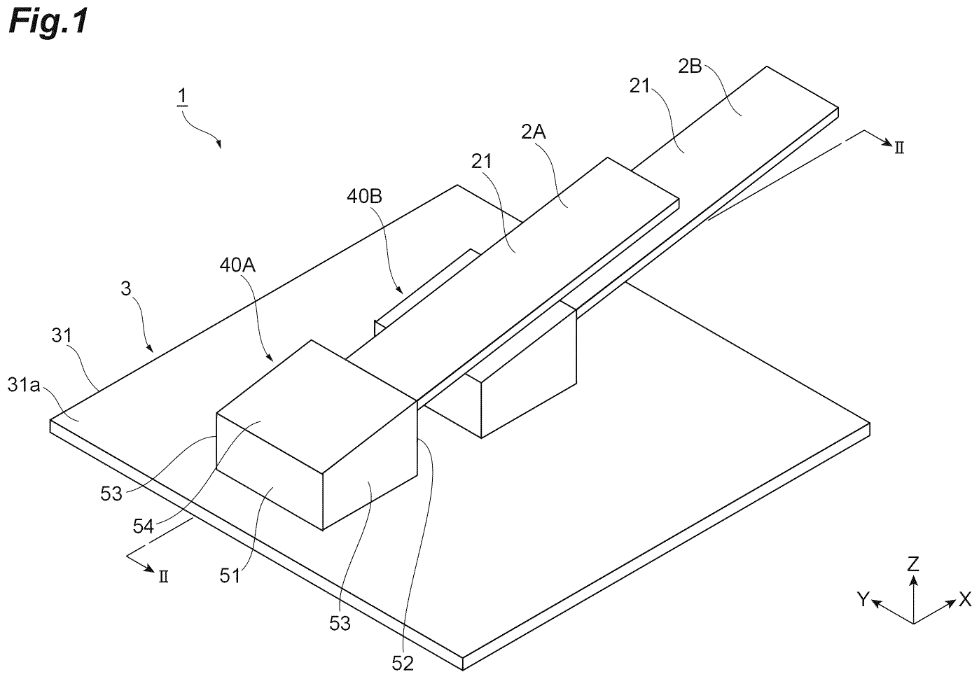

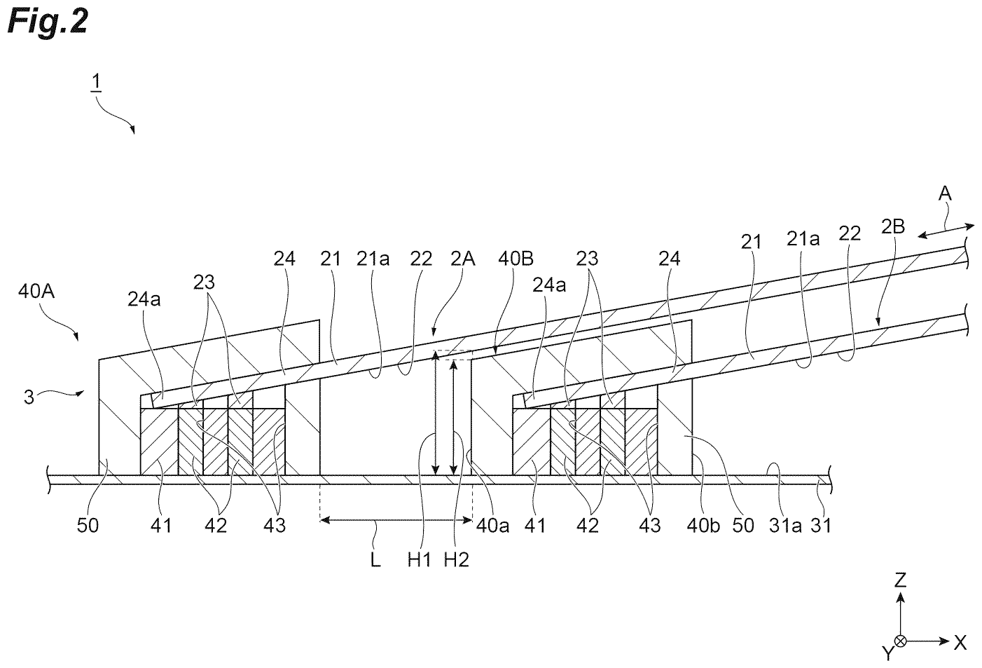

FIG. 1 is a perspective view illustrating a connection system according to an embodiment. FIG. 2 is a cross-sectional view of the connection system taken along line II-II illustrated in FIG. 1. A connection system 1 includes a plurality of flexible wiring boards 2A and 2B, and a board assembly 3. Board assembly 3 has a board body 31 and a plurality of connectors 40A and 40B. In connection system 1, the plurality of flexible wiring boards 2A and 2B are coupled to the plurality of connectors 40A and 40B of board assembly 3, respectively. Hereinafter, a direction in which flexible wiring boards 2A and 2B extend is referred to as an A-direction (first direction, second direction). In addition, directions parallel to board body 31 are referred to as an X-direction (third direction) and a Y-direction (fourth direction), and a direction perpendicular to board body 31 is referred to as a Z-direction.

As illustrated in FIG. 1 and FIG. 2, the plurality of flexible wiring boards 2A and 2B are arranged side by side in the X-direction. The plurality of flexible wiring boards 2A and 2B are, for example, flexible printed circuits (FPCs). Flexible wiring board 2A is coupled to connector 40A such that the A-direction intersects the X-direction obliquely. For example, flexible wiring board 2A is coupled to connector 40A such that the A-direction intersects the X-direction at an angle greater than 10 degrees and less than 80 degrees. Flexible wiring board 2B is coupled to connector 40B such that the A-direction intersects the X-direction obliquely. Flexible wiring board 2B is coupled to connector 40B such that the A-direction intersects the X-direction at an angle greater than 10 degrees and less than 80 degrees. An inclination angle of flexible wiring board 2B with respect to the X-direction is smaller than an inclination angle of flexible wiring board 2A with respect to the X-direction. The angle at which the A-direction intersects the X-direction may be greater than 20 degrees and less than 70 degrees, or may be greater than 30 degrees and less than 60 degrees.

Flexible wiring board 2A (first flexible wiring board) has a base film 21 (first base film), a plurality of wires 22 (a plurality of first wires), and a plurality of electrodes 23 (a plurality of first electrodes). Base film 21 is a base layer of flexible wiring board 2A and is formed of, for example, polyimide. Base film 21 has a main surface 21a. Main surface 21a extends from a rear end part (not shown) to a front end part 24 of base film 21 along the A-direction and the Y-direction.

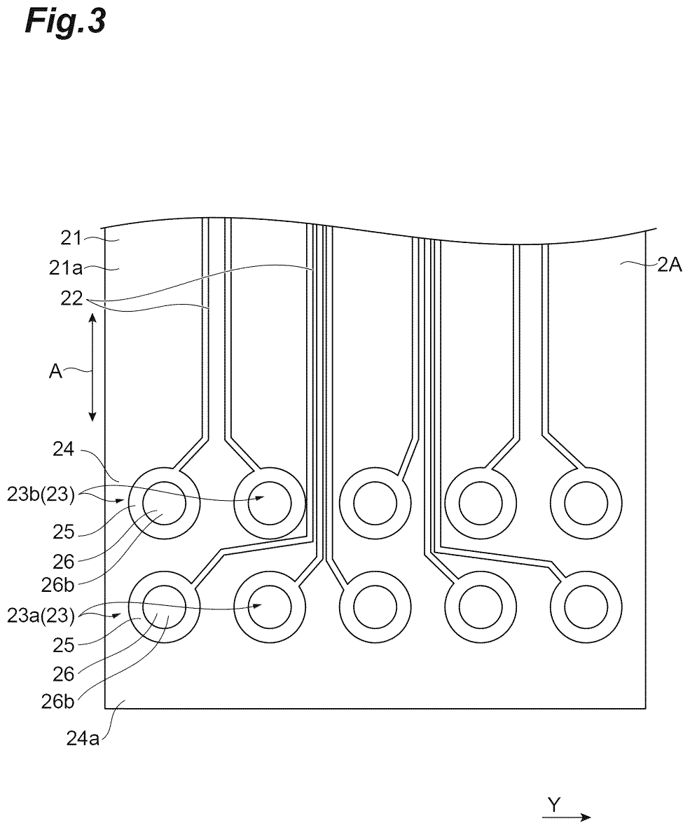

FIG. 3 is a view illustrating main surface 21a at front end part 24 of base film 21. As shown in FIG. 3, the plurality of wires 22 are provided in or on base film 21. For example, the plurality of wires 22 may be provided on main surface 21a of base film 21 or may be provided inside base film 21. As an example, the plurality of wires 22 are arranged on main surface 21a of base film 21. The plurality of wires 22 are, for example, conductive patterns or a plurality of high-speed signal lines. Each of the plurality of wires 22 extends along the A-direction. The plurality of wires 22 are arranged side by side in the Y-direction illustrated in FIG. 3. The plurality of wires 22 are formed to include at least one metal material of Au, Ti, Al, Ta, W, Cu, Pt, Mo, Ni, Pd, Zn, or Cr, for example.

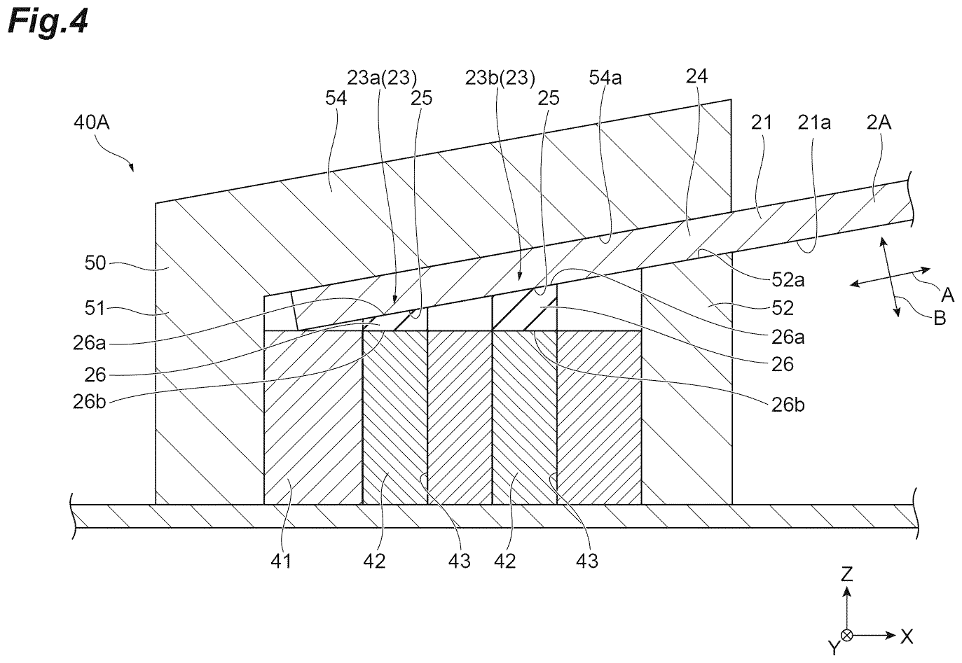

FIG. 4 is an enlarged view of connector 40A of connection system 1 illustrated in FIG. 2. As shown in FIG. 3 and FIG. 4, the plurality of electrodes 23 are provided at main surface 21a at front end part 24 of base film 21 in the A-direction. The plurality of electrodes 23 are arranged side by side in the A-direction and the Y-direction. Each of the plurality of electrodes 23 is electrically connected to a corresponding one of the plurality of wires 22. Some of the plurality of electrodes 23 are a plurality of electrodes 23a (a plurality of third electrodes) arranged side by side in the Y-direction. Other some of the plurality of electrodes 23 are a plurality of electrodes 23b (a plurality of fourth electrodes) arranged side by side in the Y-direction. The plurality of electrodes 23b are located on a side of the plurality of electrodes 23a opposite to a side where a front end 24a of front end part 24 of base film 21 is present.

The plurality of electrodes 23 are arranged at such a density that the high frequency characteristics of the plurality of wires 22 are not impaired. For example, a distance between the centers of adjacent electrodes of the plurality of electrode 23 is, for example, 2 mm. The plurality of electrodes 23 are formed to include, for example, Cu. Each of the plurality of electrodes 23 has an electrode pad 25 and a bump 26.

Electrode pad 25 is electrically connected to a corresponding one of the plurality of wires 22. Electrode pad 25 is formed in a circular film shape. Electrode pad 25 is formed to include, for example, Cu. Bump 26 is provided on electrode pad 25. Bump 26 is formed to include, for example, a solder. Electrode pad 25 is electrically and physically connected to a corresponding one of a plurality of conductors 42 (described later) with bump 26. Here, when a direction orthogonal to main surface 21a is defined as a B-direction (fifth direction), a maximum value of a length along the B-direction of bump 26 included in each of the plurality of electrodes 23b is larger than a maximum value of a length along the B-direction of bump 26 included in each of the plurality of electrodes 23a. That is, the maximum value of the length along the B-direction of each of the plurality of electrodes 23b is larger than the maximum value of the length along the B-direction of each of the plurality of electrodes 23a.

As illustrated in FIG. 4, bump 26 has a first face 26a and a second face (surface) 26b arranged in the Z-direction. First face 26a faces electrode pad 25 in the Z-direction. First face 26a extends in the A-direction and the Y-direction. First face 26a is in contact with a corresponding one of the plurality of electrode pads 25. Second face 26b is located on a side of bump 26 opposite to a side where first face 26a is present. Second face 26b extends along the X-direction and the Y-direction. Second face 26b faces conductor 42 in the Z-direction. That is, second face 26b is inclined with respect to main surface 21a. Second face 26b is located on a side opposite to a side where base film 21 is present. Second face 26b is configured to electrically and physically come into contact with a corresponding one of the plurality of conductors 42 when flexible wiring board 2A is coupled to connector 40A.

Reference is made to FIG. 1 and FIG. 2. flexible wiring board 2B (second flexible wiring board) has a configuration similar to flexible wiring board 2A, and includes a base film 21 (second base film), a plurality of wires 22 (a plurality of second wires), and a plurality of electrodes 23 (a plurality of second electrodes). Base film 21 has main surface 21a (second main surface).

Next, each configuration of board assembly 3 will be described. Board body 31 extends along the X-direction. Board body 31 has a main surface 31a (third main surface). Main surface 31a faces main surface 21a of base film 21 of flexible wiring board 2A and main surface 21a of base film 21 of flexible wiring board 2B in the Z-direction. Main surface 31a extends along the X-direction and the Y-direction.

The plurality of connectors 40A and 40B are provided at main surface 31a of board body 31. The plurality of connectors 40A and 40B are arranged side by side in the X-direction at main surface 31a. The plurality of connectors 40A and 40B are separated from each other by a length L. Connector 40A (first connector) includes a body portion 41, a plurality of conductors 42 (a plurality of first conductors), a plurality of holding holes 43, and a fixation member 50.

Body portion 41 is provided between front end part 24 of base film 21 of flexible wiring board 2A and main surface 31a of board body 31 of board assembly 3. Body portion 41 is formed to include, for example, Cu.

The plurality of conductors 42 are provided inside body portion 41 and arranged side by side in the X-direction and the Y-direction. The plurality of conductors 42 extend along the Z-direction inside body portion 41. The plurality of conductors 42 are, for example, spring pins. Each of the plurality of conductors 42 is electrically and physically in contact with a corresponding one of the plurality of electrodes 23. Each of the plurality of conductors 42 faces second face 26b of a corresponding one of the plurality of bumps 26 in the Z-direction. Each of the plurality of conductors 42 is electrically and physically in contact with second face 26b of a corresponding one of the plurality of bumps 26.

The plurality of holding holes 43 extend along the Z-direction. The plurality of holding holes 43 extend through body portion 41 in the Z-direction. A corresponding one of the plurality of conductors 42 is inserted into each of the plurality of holding holes 43.

Fixation member 50 is configured to fix flexible wiring board 2A to body portion 41 in a state in which flexible wiring board 2A is coupled to connector 40A. Fixation member 50 is provided on main surface 31a of board body 31 of board assembly 3. Fixation member 50 has a first wall 51, a second wall 52, a pair of third walls 53 (see FIG. 1), and a fourth wall 54.

First wall 51 and second wall 52 are arranged side by side in the X-direction. First wall 51 extends along the Y-direction and the Z-direction. Second wall 52 extends along the Y-direction and the Z-direction. Second wall 52 is provided with an opening 52a. Base film 21 reaches the inside of fixation member 50 through opening 52a. Front end 24a of front end part 24 of base film 21 is in contact with body portion 41 inside fixation member 50. The pair of third walls 53 are arranged side by side in the Y-direction (see FIG. 1). Each of third walls 53 extends along the X-direction and the Z-direction. Fourth wall 54 faces main surface 31a of board body 31 in the Z-direction. Fourth wall 54 extends along the A-direction and the Y-direction.

First wall 51, second wall 52, and the pair of third walls 53 are fixed to main surface 31a of board body 31 of board assembly 3, and are arranged so as to surround front end part 24 of base film 21 and body portion 41. Body portion 41 is fixed to main surface 31a. Fourth wall 54 is disposed on a side of front end part 24 of base film 21 opposite to a side where body portion 41 is present. Fourth wall 54 is integrally formed with first wall 51, second wall 52, and the pair of third walls 53. In this manner, fixation member 50 fixes front end part 24 of base film 21 to body portion 41.

Front end 24a of front end part 24 of base film 21 is in contact with body portion 41 of connector 40A. Bump 26 of each of the plurality of electrodes 23 is in contact with a corresponding one of the plurality of conductors 42. Base film 21 is in contact with inner surfaces (not shown) of the pair of third walls 53 and an inner surface 54a of fourth wall 54. In this manner, flexible wiring board 2A is held by body portion 41, the plurality of conductors 42, and fixation member 50.

Connector 40B (second connector) includes body portion 41, a plurality of conductors 42 (a plurality of second conductors), the plurality of holding holes 43, and fixation member 50, similarly to connector 40A. Connector 40B is located between main surface 21a of base film 21 of flexible wiring board 2A and main surface 31a of board body 31 of board assembly 3. Connector 40B includes a first end portion 40a and a second end portion 40b arranged side by side in the X-direction. Second end portion 40b is located on a side of first end portion 40a opposite to a side where connector 40A is present. At first end portion 40a, a distance H1 between main surface 21a and main surface 31a is larger than or equal to a height H2 of connector 40B along the Z-direction.

In connection system 1 described above, the plurality of flexible wiring boards 2A and 2B are arranged side by side in the X-direction. Flexible wiring board 2A is coupled to connector 40A such that the A-direction in which main surface 21a extends intersects the X-direction obliquely. Flexible wiring board 2B is coupled to connector 40B such that the A-direction in which main surface 21a extends intersects the X-direction obliquely. According to connection system 1, the plurality of flexible wiring boards 2A and 2B extend in the A-direction intersecting the X-direction, and thus, when the plurality of flexible wiring boards 2A and 2B are arranged side by side in the X-direction, the interference between flexible wiring boards 2A and 2B is prevented. Thus, the plurality of flexible wiring boards 2A and 2B can be arranged at a high density along the X-direction. As a result, the plurality of wires 22 can be arranged at a high density not only in the Y-direction but also in the X-direction. For example, the number of channels in connection system 1 can be increased. Furthermore, in the above-described connection system 1, each of the plurality of electrodes 23 is configured to be electrically connected to a corresponding one of the plurality of conductors 42 when flexible wiring board 2A is coupled to connector 40A. In addition, each of the plurality of electrodes 23 is configured to be electrically connected to a corresponding one of the plurality of conductors 42 when flexible wiring board 2B is coupled to connector 40B. According to connection system 1, wires 22 in the plurality of flexible wiring boards 2A and 2B, and conductors 42 in the plurality of connectors 40A and 40B can be electrically connected with a simple structure. This can prevent the deterioration of the high frequency characteristics in connection system 1. As described above, the plurality of wires 22 can be arranged at a high density while the deterioration of the high frequency characteristics is prevented in connection system 1. In addition, since the plurality of flexible wiring boards 2A and 2B are coupled to the plurality of connectors 40A and 40B, respectively, such that the A-direction intersects the X-direction obliquely, a length of connection system 1 along the Z-direction is reduced. This makes it possible to further reduce the height of connection system 1. For example, the height of connection system 1 can be further reduced than in a case where a plurality of flexible wiring boards extend along the X-direction and are arranged along the Z-direction.

In connection system 1, flexible wiring board 2A is coupled to connector 40A such that the A-direction in which main surface 21a extends intersects the X-direction at an angle greater than 10 degrees and less than 80 degrees. In this case, when the A-direction in which main surface 21a extends intersects the X-direction at an angle greater than 10 degrees, flexible wiring board 2A and flexible wiring board 2B can be prevented from coming into contact with each other, and thus the plurality of wires 22 can be arranged at a higher density. In addition, when the A-direction in which main surface 21a extends intersects with the X-direction at an angle less than 80 degrees, the height of connection system 1 can be sufficiently reduced.

In connection system 1, the inclination angle of flexible wiring board 2B with respect to the X-direction is smaller than the inclination angle of flexible wiring board 2A with respect to the X-direction. In this case, it is possible to prevent the interference between flexible wiring board 2A and flexible wiring board 2B. As a result, the plurality of flexible wiring boards 2A and 2B can be arranged at a high density, and thus the plurality of wires 22 can be arranged at a higher density.

In connection system 1, connector 40A includes body portion 41 and fixation member 50 configured to fix flexible wiring board 2A to body portion 41 in a state in which flexible wiring board 2A is coupled to connector 40A. In this case, when flexible wiring board 2A is coupled to connector 40A, each of the plurality of electrodes 23 can be electrically connected to a corresponding one of the plurality of conductors 42 in a stable manner.

In connection system 1, connector 40A has a plurality of holding holes 43 extending through body portion 41 and into each of which a corresponding one of the plurality of conductors 42 is inserted. In this case, when flexible wiring board 2A is coupled to connector 40A, each of the plurality of electrodes 23 can be electrically connected to a corresponding one of the plurality of conductors 42 in a more stable manner.

In connection system 1, each of the plurality of electrodes 23 includes electrode pad 25 that is electrically connected to a corresponding one of the plurality of wires 22, and bump 26 provided on electrode pad 25. In this case, wires 22 in flexible wiring board 2A and conductors 42 in connector 40A can be electrically connected with a simpler structure. This makes it possible to further prevent the deterioration of the high frequency characteristics in connection system 1.

In connection system 1, some of the plurality of electrodes 23 are the plurality of electrodes 23a arranged side by side in the Y-direction. Other some of the plurality of electrodes 23 are the plurality of electrodes 23b arranged side by side in the Y-direction and located on a side of the plurality of electrodes 23a opposite to a side where front end 24a of front end part 24 of base film 21 is present. A maximum value of a length along the B-direction of bump 26 included in each of the plurality of electrodes 23b may be larger than a maximum value of a length along the B-direction of bump 26 included in each of the plurality of electrodes 23a. In this case, when flexible wiring board 2A is coupled to connector 40A such that the A-direction intersects the X-direction obliquely, the plurality of electrodes 23 can stably support base film 21, and each of the plurality of electrodes 23 can more reliably come into contact with a corresponding one of the plurality of conductors 42. Thus, each of the plurality of electrodes 23 can be electrically connected to a corresponding one of the plurality of conductors 42 in a stable manner.

In connection system 1, bump 26 has first face 26a that extends along the A-direction and is in contact with a corresponding one of the plurality of electrode pads 25, and second face 26b that extends along the X-direction and is located on a side of bump 26 opposite to a side where first face 26a is present. Second face 26b is configured to come into contact with a corresponding one of the plurality of conductors 42 when flexible wiring board 2A is coupled to connector 40A. In this case, flexible wiring board 2A is stably supported by connector 40A through the plurality of bumps 26. This makes it possible to electrically connect each of the plurality of electrodes 23 to a corresponding one of the plurality of conductors 42 in a more stable manner.

Although connection system 1 according to the present disclosure has been described in detail, the present invention is not limited to the above embodiments, and can be applied to various embodiments and modifications.

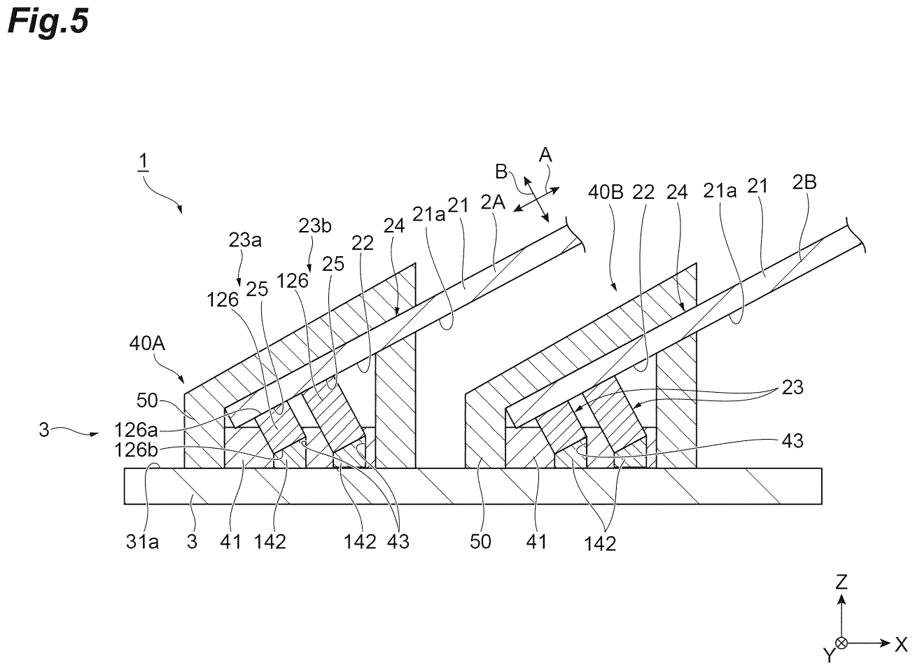

FIG. 5 is a cross-sectional view illustrating a connection system according to a modification. As shown in FIG. 5, each of the plurality of electrodes 23 may include a bump 126 instead of bump 26, and connector 40A may include a plurality of conductors 142 instead of the plurality of conductors 42.

Bump 126 has a first face 126a and a second face 126b. First face 126a extends along the A-direction and the Y-direction. First face 126a is in contact with a corresponding one of the plurality of electrode pads 25. Second face 126b is located on a side of bump 126 opposite to a side where first face 126a is present. Second face 126b extends along the A-direction and the Y-direction. A maximum value of a length along the B-direction of bump 126 included in each of the plurality of electrodes 23b is larger than a maximum value of a length along the B-direction of bump 126 included in each of the plurality of electrodes 23a.

Each of the plurality of conductors 142 (a plurality of first conductors) faces second face 126b of a corresponding one of the plurality of bumps 126 in the Z-direction. Each of the plurality of conductors 142 is electrically and physically in contact with a corresponding one of the plurality of bumps 126 when flexible wiring board 2A is coupled to connector 40A.

In this case, flexible wiring board 2A is stably supported by connector 40A through the plurality of bumps 126. This makes it possible to electrically connect each of the plurality of electrodes 23 to a corresponding one of the plurality of conductors 42 in a more stable manner.

What is claimed is:

1. A connection system comprising:
a first flexible wiring board including a first base film, a plurality of first wires, and a plurality of first electrodes, the first base film having a first main surface extending along a first direction, the plurality of first wires being provided in or on the first base film, the plurality of first electrodes being provided on the first main surface at a front end part of the first base film along the first direction and being each electrically connected to a corresponding one of the plurality of first wires;
a second flexible wiring board including a second base film, a plurality of second wires, and a plurality of second electrodes, the second base film having a second main surface extending along a second direction, the plurality of second wires being provided in or on the second base film, the plurality of second electrodes being provided on the second main surface at a front end part of the second base film along the second direction and being each electrically connected to a corresponding one of the plurality of second wires; and
a board assembly including a board body, a first connector, and a second connector, the board body having a third main surface extending along a third direction, the first connector being provided at the third main surface and including a plurality of first conductors, the second connector being provided at the third main surface and including a plurality of second conductors, the first connector and the second connector being arranged side by side in the third direction,
wherein the first main surface faces the third main surface and each of the plurality of first electrodes is electrically connected to a corresponding one of the plurality of first conductors, when the first flexible wiring board is coupled to the first connector, and
wherein the second main surface faces the third main surface and each of the plurality of second electrodes is electrically connected to a corresponding one of the plurality of second conductors, when the second flexible wiring board is coupled to the second connector,
wherein the first flexible wiring board is configured to couple to the first connector such that the first direction in which the first main surface extends intersects the third direction obliquely,
wherein the second flexible wiring board is configured to couple to the second connector such that the second direction in which the second main surface extends intersects the third direction obliquely.

2. The connection system according to claim 1,
wherein an inclination angle of the second flexible wiring board with respect to the third direction is smaller than an inclination angle of the first flexible wiring board with respect to the third direction.

3. The connection system according to claim 1,
wherein the first connector further includes a body portion and a fixation member configured to fix the first flexible wiring board to the body portion in a state in which the first flexible wiring board is coupled to the first connector.

4. The connection system according to claim 3,
wherein the first connector further has a plurality of holding holes extending through the body portion and into each of which a corresponding one of the plurality of first conductors is inserted.

5. The connection system according to claim 1,
wherein the second connector is located between the first main surface of the first base film of the first flexible wiring board and the third main surface of the board body of the board assembly,
wherein the second connector further includes a first end portion and a second end portion, the first end portion and the second end portion being arranged side by side in the third direction,
wherein the second end portion is located on a side of the first end portion opposite to a side where the first connector is present, and
wherein, at the first end portion, a distance between the first main surface and the third main surface is larger than or equal to a height of the second connector.

6. The connection system according to claim 1,
wherein each of the plurality of first electrodes includes an electrode pad and a bump provided at the electrode pad, the electrode pad being electrically connected to a corresponding one of the plurality of first wires.

7. The connection system according to claim 6,
wherein some of the plurality of first electrodes are a plurality of third electrodes arranged side by side in a fourth direction intersecting the first direction and the third direction,
wherein other some of the plurality of first electrodes are a plurality of fourth electrodes arranged side by side in the fourth direction and being located on a side of the plurality of third electrodes opposite to a side where a front end of a front end part of the base film is present, and
wherein a maximum value of a length of the bump included in each of the plurality of fourth electrodes, the length being along a fifth direction orthogonal to the first main surface, is larger than a maximum value of a length of the bump included in each of the plurality of third electrode, the length being along the fifth direction.

8. The connection system according to claim 6,
wherein the bump has a first face and a second face, the first face being in contact with the electrode pad, the second face extending along the third direction and being located on a side of the bump opposite to a side where the first face is present, and
wherein the second face is configured to come into contact with a corresponding one of the plurality of first conductors when the first flexible wiring board is coupled to the first connector.

9. The connection system according to claim 6,
wherein the bump has a first face and a second face, the first face being in contact with the electrode pad, the second face extending along the first direction and being located on a side of the bump opposite to a side where the first face is present, and
wherein the second face is configured to come into contact with a corresponding one of the plurality of first conductors when the first flexible wiring board is coupled to the first connector.

10. A flexible wiring board capable of being coupled to a board assembly including a board body, the flexible wiring board comprising:
a base film having a main surface extending so as to obliquely intersect a direction in which the board body extends;
a plurality of wires provided in or on the base film; and
a plurality of electrodes provided at the main surface at a front end part of the base film in the direction in which the board body extends, the plurality of electrodes being each electrically connected to a corresponding one of the plurality of wires.

11. A flexible wiring board comprising:
a base film having a main surface;
a plurality of wires provided in or on the base film; and
a plurality of electrodes provided at the main surface at a front end part of the base film, the plurality of electrodes being each electrically connected to a corresponding one of the plurality of wires,
wherein each of the plurality of electrodes has a surface located on a side opposite to a side where the base film is present, the surface being inclined with respect to the main surface.

12. A board assembly capable of being coupled to a plurality of flexible wiring boards each including a base film and a plurality of electrodes, the base film having a first main surface, the plurality of electrodes being provided at the first main surface, the board assembly comprising:
a board body having a third main surface extending along a direction obliquely intersecting the extending direction of the first main surface; and
a plurality of connectors arranged side by side in the extending direction of the third main surface at the third main surface and each including a plurality of conductors,
wherein each of the plurality of conductors is configured to be electrically connected to a corresponding one of the plurality of electrodes when the connectors are coupled to the flexible wiring boards.

13. The board assembly according to claim 12,
wherein each of the connectors further includes a body portion and a fixation member configured to fix each flexible wiring board to each body portion in a state in which each flexible wiring board is coupled to each connector.
